(19) United States
(12) Patent Application Publication
(10) Pub. No.: US 2015/0228625 A1
(43) Pub. Date: Aug. 13, 2015

(54) SEMICONDUCTOR PACKAGE AND METHOD OF MANUFACTURING THE SAME

(71) Applicant: SAMSUNG ELECTRO-MECHANICS CO., LTD., Suwon-Si (KR)

(72) Inventors: Jae Hyun Lim, Suwon-Si (KR); Do Jae Yoo, Suwon-Si (KR); Eun Jung Jo, Suwon-Si (KR); Kyu Hwan Oh, Suwon-Si (KR); Jong In Ryu, Suwon-Si (KR)

(73) Assignee: SAMSUNG ELECTRO-MECHANICS CO., LTD., Suwon-Si (KR)

(21) Appl. No.: 14/607,062

(22) Filed: Jan. 27, 2015

(30) Foreign Application Priority Data
Feb. 10, 2014 (KR) 10-2014-0015151

(51) Int. Cl. H01L 25/065; H01L 21/56; H01L 51/50; H01L 23/522; H01L 23/31

(52) U.S. Cl. CPC H01L 25/0657; H01L 23/5226; H01L 23/3107; H01L 51/50; H01L 21/56

(57) ABSTRACT

There are provided a semiconductor package and a method of manufacturing the same. According to an exemplary embodiment of the present disclosure, a semiconductor package includes: a semiconductor device formed in a multilayer; a plurality of wires electrically connected to both sides of a plurality of semiconductor devices; a first mold via electrically connected to the plurality of wires which are formed at one side of the plurality of semiconductor devices; a second mold via electrically connected to the plurality of wires which are formed at the other side of the plurality of semiconductor device; and a first molding part enclosing the plurality of semiconductor device and formed to expose upper surface parts of the first mold via and the second mold via.

### CROSS-REFERENCE TO RELATED APPLICATION

This application claims the benefit of Korean Patent Application No. 10-2014-0015151, filed on Feb. 10, 2014, entitled “Semiconductor Package And Method Of Manufacturing The Same” which is hereby incorporated by reference in its entirety into this application.

### BACKGROUND

The present disclosure relates to a semiconductor package and a method of manufacturing the same.

With the increased demand for small-sized and high-performance IT devices, a large-capacity memory and high-performance IC have been demanded.

The existing package has technical limitations in achieving both integration and high performance which are currently being demanded. To solve the above problem, many researches for implementing 3D package by various methods have been conducted and a need exists for new interconnection technology development. A die stack and package stack structures which are one of the above methods have been generally applied.

### RELATED ART DOCUMENT

### Patent Document

(Patent Document 1) Korean Patent Laid-Open Publication No. 2012-0004877

### SUMMARY

An aspect of the present disclosure may provide a semiconductor package and a method of manufacturing the same capable of reducing a package size by connecting wires, which are connected to each of the stacked devices, to one mold via.

Another aspect of the present disclosure may provide a semiconductor package and a method of manufacturing the same capable of mounting a main board by having a terminal structure in which upper and lower ends of a mold via which is connected to wires connected to each of the stacked devices are exposed.

According to an aspect of the present disclosure, a semiconductor package may include: a plurality of semiconductor devices; a plurality of wires electrically connected to both sides of the plurality of semiconductor devices; a first mold via electrically connected to the plurality of wires which are formed at one side of the plurality of semiconductor devices; a second mold via electrically connected to the plurality of wires which are formed at the other side of the plurality of semiconductor devices; and a molding part enclosing the plurality of semiconductor devices and formed to expose upper surface parts of the first mold via and the second mold via.

The semiconductor package may further include: a substrate formed on upper and lower portions of the first mold via and the second mold via.

The semiconductor package may further include: an external connection terminal connected between the first mold via and the second mold via and the substrate.

According to another aspect of the present disclosure, a semiconductor package may include: a first package including a first semiconductor device formed in a multilayer, a plurality of wires electrically connected to both sides of the first semiconductor device, a first mold via electrically connected to the plurality of wires which are formed at one side of the first semiconductor device, a second mold via electrically connected to the plurality of wires which are formed at the other side of the first semiconductor device, and a first molding part enclosing the first semiconductor device and formed to expose upper surface parts of the first mold via and the second mold via; and a second package including a second substrate and a second semiconductor device formed under the first package.

The semiconductor package may further include: a first substrate formed over the first package.

The semiconductor package may further include: a third package formed between the first package and the first substrate.

The semiconductor package may further include: a first external connection terminal formed between the first package and the second package.

The semiconductor package may further include: a second external connection terminal formed between the first package and the first substrate.

The semiconductor package may further include: a third external connection terminal formed between the third package and the first substrate.

The second package may further include a second molding part.

According to another aspect of the present disclosure, a method of manufacturing a semiconductor package may include: preparing a plurality of lower semiconductor devices arrayed in a line; forming a plurality of wires electrically connecting adjacent devices among the lower semiconductor devices to each other; forming a molding part to enclose the lower semiconductor device and the wire; forming a mold via hole to penetrate through the molding part and the wire; forming a mold via by performing plating on the mold via hole; and sawing between the adjacent two mold via holes to separate the two mold via holes from each other.

The method may further include: prior to the preparing of the lower semiconductor device, forming the lower semiconductor device arrayed in a line on a protective film; and after the forming of the molding part, removing the protective film.

The method may further include: after the forming of the wire, forming an adhesive on the lower semiconductor device; and forming an upper semiconductor device on the adhesive.

The lower semiconductor device and the upper semiconductor device may be the same device.

The lower semiconductor device and the upper semiconductor device may be different devices.

The method may further include: after the forming of the mold via, forming an external connection terminal over the mold via.

The method may further include: forming a substrate over or under the mold via.

### BRIEF DESCRIPTION OF DRAWINGS

The above and other aspects, features and other advantages of the present disclosure will be more clearly understood from the following detailed description taken in conjunction with the accompanying drawings, in which:

FIGS. 1 to 3 are a cross-sectional view of a semiconductor package according to an exemplary embodiment of the present disclosure; and

FIGS. 4 to 13 are process flow diagrams illustrating a method of manufacturing a semiconductor package according to another exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

### Semiconductor Package

### First Exemplary Embodiment

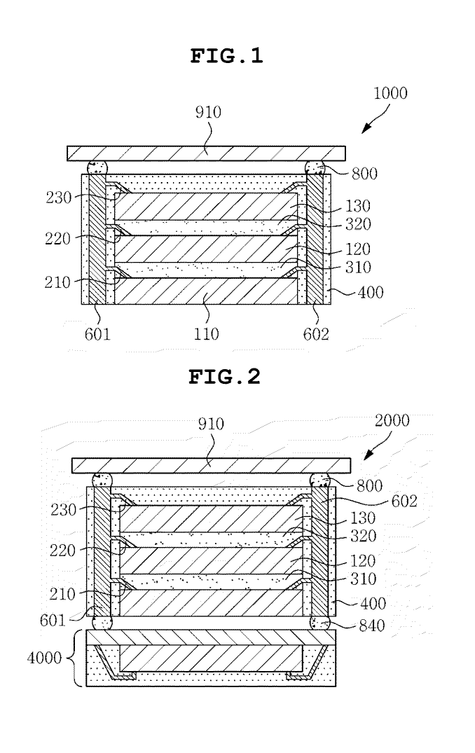

FIG. 1 is a cross-sectional view of a semiconductor package according to a first exemplary embodiment of the present disclosure.

As illustrated in FIG. 1, a semiconductor package 1000 according to an exemplary embodiment of the present disclosure includes a plurality of semiconductor devices 101, 102, and 103, a plurality of wires 210, 220, and 230 which are electrically connected to both sides of the plurality of semiconductor devices 101, 102, and 103, a first mold via 601 to which the plurality of wires 210, 220, and 230 formed at one side of the plurality of semiconductor devices 101, 102, and 103 are electrically connected, a second mold via 602 to which the plurality of wires 210, 220, and 230 formed at the other side of the plurality of semiconductor devices 101, 102, and 103 are electrically connected, and a molding part 400 which encloses the plurality of semiconductor devices 101, 102, and 103 and is formed to expose upper surface portions of the first mold via 601 and the second mold via 602.

According to the exemplary embodiment of the present disclosure, the first mold via 601 and the second mold via 602 may electrically connect the semiconductor devices 101, 102, and 103 to a first substrate 910.

The first mold via 601 and the second mold via 602 may be made of a conductive material for a circuit.

Here, upper or lower portion of the first mold via 601 and the second mold via 602 may be further provided with the first substrate 910, but the number and positions of first substrates 910 may be selectively formed.

In this case, an external connection terminal 800 may be formed between the first mold via 601 and the second mold via 602 and the first substrate 910.

According to the present exemplary embodiment, as the external connection terminal 800, a solder ball is used but the present exemplary embodiment is not limited thereto.

The semiconductor devices 101, 102, and 103 may include a power device and a control device, but the present exemplary embodiment is not limited thereto. For example, the power device is a device having a large heating value such as an insulated gate bipolar transistor (IGBT) and a diode and the control device is a device having a small heating value such as a control integrated circuit (control IC).

Although the semiconductor devices 101, 102, and 103 are schematically illustrated in FIG. 1 without showing other detailed components thereof, semiconductor devices having all structures known in the art may be used without special limitation.

Further, according to the present exemplary embodiment, the semiconductor device is formed in three layers but the present exemplary embodiment is not limited thereto, and the semiconductor package 1000 may be stacked in one layer or at least two layers.

Both sides of each of the semiconductor devices 101, 102, and 103 may be provided with wires 210, 220, and 230.

Here, the wires 210, 220 and 230 may be aluminum (Al), gold (Au), copper (Cu), and the like, but the present exemplary embodiment is not particularly limited thereto. Generally, as a wire applying a high rated voltage to semiconductor components which are the power devices, aluminum (Al) may be used.

In this case, the plurality of wires 210, 220, and 230 which are formed at one side of the semiconductor device may be electrically connected to one first mold via 601. Further, the plurality of wires 210, 220, and 230 which are formed at the other side of the semiconductor device may be electrically connected to one second mold via 602.

According to the related art, the plurality of wires connected to each of the stacked semiconductor devices are directly connected to a substrate and thus the package size is increased as a height of the stack is large. However, according to the present exemplary embodiment, the plurality of wires are not directly connected to the substrate but are connected to the one mold via, thereby reducing the package size.

Further, the molding part 400 may be formed to cover the semiconductor devices 101, 102, and 103.

In this case, an upper surface of the molding part 400 may be positioned on the same line as the upper surface portions of the first mold via 601 and the second mold via 602. This is to electrically connect the first mold via 601 and the second mold via 602 to the substrate by exposing the upper surface portions of the first mold via 601 and the second mold via 602 to the outside.

Here, as the material of the molding part 400, a silicon gel, an epoxy molding compound (EMC), or the like, may be used, but the present exemplary embodiment is not limited thereto.

### Second Exemplary Embodiment

FIG. 2 is a cross-sectional view of a semiconductor package according to a second exemplary embodiment of the present disclosure.

As illustrated in FIG. 2, a semiconductor package 2000 according to another exemplary embodiment of the present disclosure includes: a first package which includes first semiconductor devices 110, 120, and 130 formed in a multilayer, the plurality of wires 210, 220, and 230 electrically connected to both sides of the first semiconductor devices 110, 120, and 130, the first mold via 601 electrically connected to the plurality of wires 210, 220, and 230 formed at one side of the first semiconductor devices 110, 120, and 130, the second mold via 602 electrically connected to the plurality of wires 210, 220, and 230 formed at the other side of the first semiconductor devices 110, 120, and 130, and a first molding part 400 enclosing the first semiconductor devices 110, 120, and 130 and formed to expose the upper surface portions of the first mold via 601 and the second mold via 602; and a second package 4000 which includes a second substrate and a second semiconductor device formed under the first package.

According to the exemplary embodiment of the present disclosure, the first mold via 601 and the second mold via 602 may electrically connect the first semiconductor devices 110, 120, and 130 to the first substrate 910 or the second package 4000.

The first semiconductor devices 110, 120, and 130 may include a power device and a control device, but the present exemplary embodiment is not limited thereto. For example, the power device is a device having a large heating value such as an insulated gate bipolar transistor (IGBT) and a diode and the control device is a device having a small heating value such as a control integrated circuit (control IC).

Both sides of each of the first semiconductor devices 110, 120, and 130 may be provided with the wires 210, 220, and 230.

Here, the wires 210, 220 and 230 may be aluminum (Al), gold (Au), copper (Cu), and the like, but the present exemplary embodiment is not particularly limited thereto. In this case, the plurality of wires 210, 220, and 230 which are formed at one side of the first semiconductor devices 110, 120, and 130 may be electrically connected to the one first mold via 601. Further, the plurality of wires 210, 220, and 230 which are formed at the other side of the first semiconductor devices 110, 120, and 130 may be electrically connected to the one second mold via 602.

In this case, a first external connection terminal 810 may be formed between the first mold via 601 and the second mold via 602 which are formed in the first package and the second package. According to the present exemplary embodiment, as the first external connection terminal 810, a solder ball is used but the present exemplary embodiment is not limited thereto.

Here, upper or lower portion of the first mold via 601 and the second mold via 602 may be further provided with the first substrate 910, but the number and positions of substrates 910 may be selectively formed.

In this case, a second external connection terminal 820 may be formed between the first mold via 601 and the second mold via 602 and the first substrate 910.

According to the present exemplary embodiment, as the second external connection terminal 820, the solder ball is used, but the present exemplary embodiment is not limited thereto.

Further, the second package 4000 may further include the second molding part and if not necessary, the second molding part may be omitted.

Further, the substrate of the second package 4000 may be mounted with the semiconductor device, and as a means for electrical connection, the wire may be used, but the present exemplary embodiment is not particularly limited thereto.

### Third Exemplary Embodiment

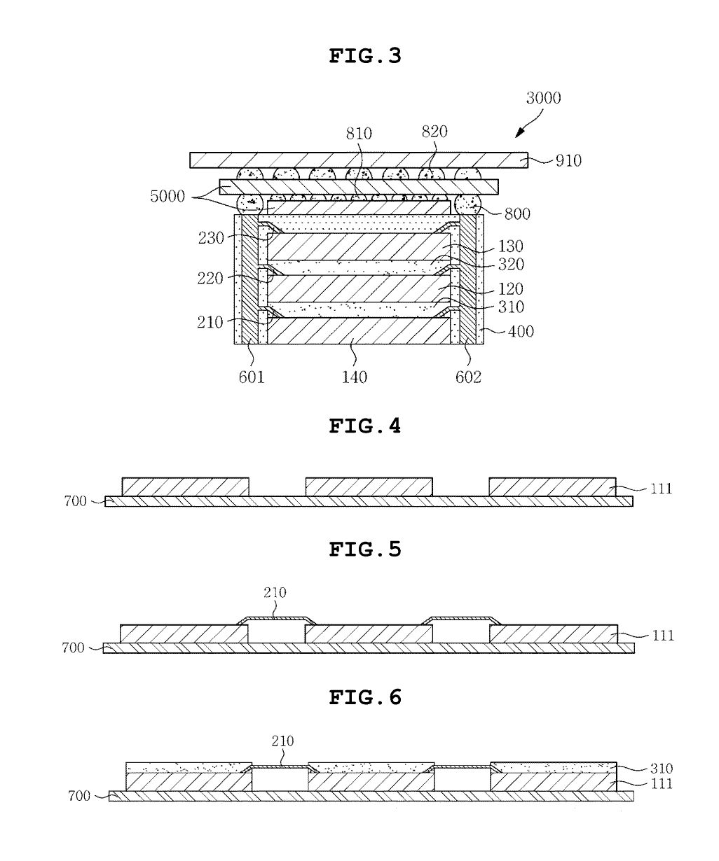

FIG. 3 is a cross-sectional view of a semiconductor package according to a third exemplary embodiment of the present disclosure.

As illustrated in FIG. 3, a semiconductor package 3000 according to another exemplary embodiment of the present disclosure includes: a first package which includes first semiconductor devices 110, 120, and 130 formed in a multilayer, the plurality of wires 210, 220, and 230 electrically connected to both sides of the first semiconductor devices 110, 120, and 130, the first mold via 601 electrically connected to the plurality of wires 210, 220, and 230 formed at one side of the first semiconductor devices 110, 120, and 130, the second mold via 602 electrically connected to the plurality of wires 210, 220, and 230 formed at the other side of the first semiconductor devices 110, 120, and 130, and a first molding part 400 enclosing the first semiconductor devices 110, 120, and 130 and formed to expose the upper surface portions of the first mold via 601 and the second mold via 602; and a third package 5000 which includes a third substrate and a third semiconductor device formed over the first package.

According to the exemplary embodiment of the present disclosure, the first mold via 601 and the second mold via 602 may electrically connect the first semiconductor devices 110, 120, and 130 to the third package 5000.

The first semiconductor devices 110, 120, and 130 may include a power device and a control device, but the present exemplary embodiment is not limited thereto. For example, the power device is a device having a large heating value such as an insulated gate bipolar transistor (IGBT) and a diode and the control device is a device having a small heating value such as a control integrated circuit (control IC).

Both sides of each of the first semiconductor devices 110, 120, and 130 may be provided with the wires 210, 220, and 230.

Here, the wires 210, 220 and 230 may be aluminum (Al), gold (Au), copper (Cu), and the like, but the present exemplary embodiment is not particularly limited thereto.

In this case, the plurality of wires 210, 220, and 230 which are formed at one side of the first semiconductor devices 110, 120, and 130 may be electrically connected to the one first mold via 601. Further, the plurality of wires 210, 220, and 230 which are formed at the other side of the first semiconductor devices 110, 120, and 130 may be electrically connected to the one second mold via 602.

In this case, the first external connection terminal 810 may be formed between the first mold via 601 and the second mold via 602 which are formed in the first package and the third package 5000. According to the present exemplary embodiment, as the first external connection terminal 810, a solder ball is used but the present exemplary embodiment is not limited thereto.

Further, the first substrate 910 may be further formed on the third package 5000.

In this case, a third external connection terminal 830 may be further formed between the third package 5000 and the first substrate 910.

Here, the substrate of the third package 5000 and the semiconductor device are electrically connected to each other by the solder ball, but the present exemplary embodiment is not limited thereto.

Method of Manufacturing Semiconductor Package

FIGS. 4 to 13 are process flow diagrams illustrating a method of manufacturing a semiconductor package according to another exemplary embodiment of the present disclosure.

As illustrated in FIG. 4, a plurality of lower semiconductor devices 111 which are arrayed on a protective film 700 in a line are prepared.

According to the present exemplary embodiment, three lower semiconductor devices 111 are formed in a line, but the number of devices is not particularly limited thereto.

Here, the lower semiconductor device 111 may include a power device and a control device, but the present exemplary embodiment is not limited thereto. For example, the power device is a device having a large heating value such as an insulated gate bipolar transistor (IGBT) and a diode and the control device is a device having a small heating value such as a control integrated circuit (control IC).

Although the semiconductor device is schematically illustrated in the drawings without showing other detailed components thereof, semiconductor devices having all structures known in the art may be used without special limitation.

As illustrated in FIG. 5, the plurality of wires 210 which electrically connect adjacent devices among the lower semiconductor devices 111 to each other may be formed.

In this case, as the wire 210, aluminum (Al), gold (Au), copper (Cu), and the like may be used, but the present exemplary embodiment is not particularly limited thereto. Generally, as the wire applying a high rated voltage to semiconductor components which are the power devices, aluminum (Al) may be used.

As illustrated in FIG. 6, an adhesive 310 may be formed on the lower semiconductor device 111. In this case, the adhesive 310 may be formed to partially cover the wire 210.

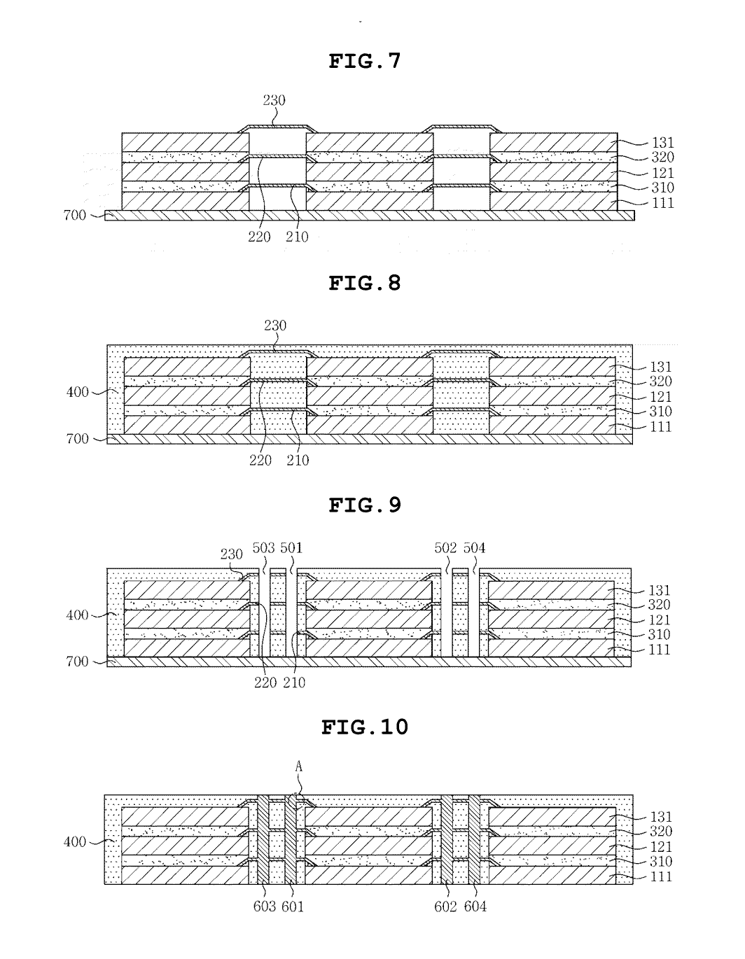

As illustrated in FIG. 7, the upper semiconductor device 121 may be formed on the formed adhesive 310. Further, an adhesive 320 is formed on an upper semiconductor device 121 and then an upper semiconductor device 131 may be further formed thereon.

According to the present exemplary embodiment, the semiconductor devices 111, 121, and 131 are formed in a three-layer form but may be formed in a multilayer according to a selection of those skilled in the art.

Here, a plurality of wires 220 and 230 which electrically connect adjacent devices of the upper semiconductor devices 121 and 131 to each other may be formed together.

As illustrated in FIG. 8, the molding part 400 may be formed to cover the lower and upper semiconductor devices 111, 121, and 131 and the plurality of wires 210, 220, and 230.

Here, as the material of the molding part 400, a silicon gel, an epoxy molding compound (EMC), and the like, may be used, but the present exemplary embodiment is not limited thereto.

As illustrated in FIG. 9, mold via holes 501, 502, 503, and 504 may be formed to vertically penetrate through the molding part 400 and the plurality of wires 201, 220, and 230.

Here, the vertical direction indicates one direction which is formed in a gravity direction and is not necessarily limited to the positions of the drawing according to the exemplary embodiment of the present disclosure.

In this case, as a method for forming the mold via holes 501, 502, 503, and 504, a CO₂ laser and a YAG laser may be used, but the present exemplary embodiment is not particularly limited thereto.

As illustrated in FIG. 10, the mold vias 601, 602, 603, and 604 may be formed by performing plating on the mold via holes 501, 502, 503, and 504.

In this case, after laser machining is performed, a portion of the wire may be exposed to the molding part, in which the exposed portion A may be plated with a conductive material.

Therefore, the plurality of wires connected to each of the stacked semiconductor devices are connected to one of the mold vias 601, 602, 603, and 604, thereby reducing the package size.

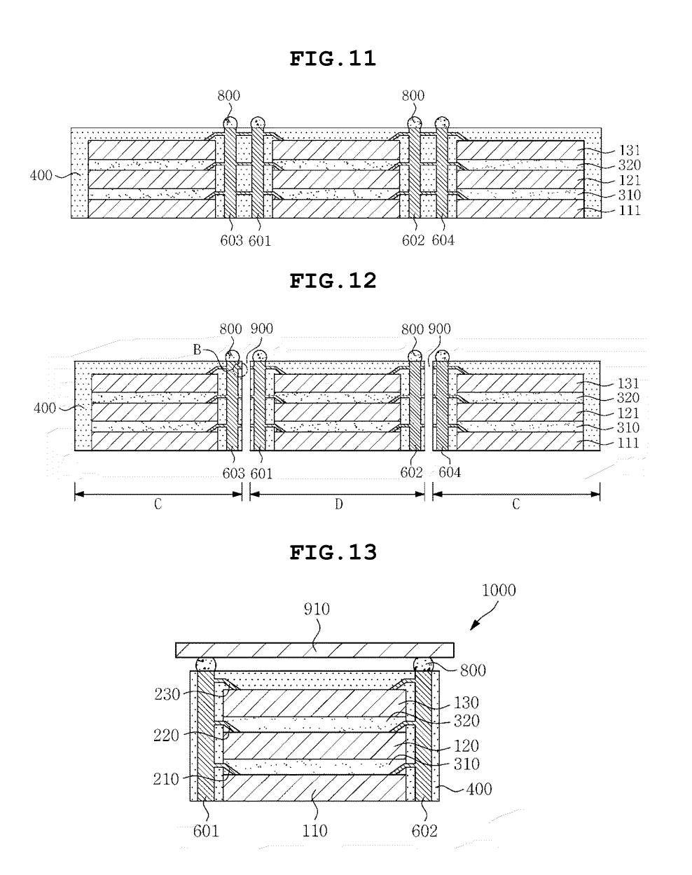

As illustrated in FIG. 11, the external connection terminal 800 may be formed on the formed mold vias 601, 602, 603, and 604.

According to the present exemplary embodiment, the external connection terminal 800 is formed as the solder ball, but the present exemplary embodiments are not particularly limited thereto.

As illustrated in FIG. 12, sawing may be performed to vertically penetrate through the wire between the formed mold via 601 and the adjacent mold via 603. As a result, it is possible to separate the mold vias 601 and 604 from the adjacent mold vias 603 and 602.

Further, after the sawing, a protruding wire region (B) may be selectively coated with an insulating material.

According to the present exemplary embodiment, region (C) is a dummy region using a dummy semiconductor device and may not be used.

Alternatively, instead of the dummy semiconductor device of the region (C), the printed circuit board may be formed, but the present exemplary embodiment is not particularly limited thereto.

As illustrated in FIG. 13, the first substrate 910 may be formed to be electrically connected to the external connection terminal 800.

Here, region (D) may be applied.

In the method of manufacturing a semiconductor package according to the exemplary embodiment of the present disclosure, for convenience of explanation, the semiconductor devices 101, 102, and 103 of FIG. 1 are described by being divided into the lower semiconductor device 111 and the upper semiconductor devices 121 and 131. However, the semiconductor package 1000 of FIG. 1 and a semiconductor package 6000 of FIGS. 4 to 13 are denoted by different reference numerals, but it is apparent to those skilled in the art that the configurations thereof are the same.

As set forth above, according to the exemplary embodiments of the present disclosure, the semiconductor package and the method of manufacturing the same may reduce the package size by connecting the wires, which are connected to each of the stacked devices, to one mold via.

Further, the semiconductor package may take the structure to mount the main board.

Further, since the semiconductor package does not require the printed circuit board, costs may be saved.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A semiconductor package, comprising:
a plurality of semiconductor devices;
a plurality of wires electrically connected to both sides of the plurality of semiconductor devices;
a first mold via electrically connected to the plurality of wires which are formed at one side of the plurality of semiconductor devices;
a second mold via electrically connected to the plurality of wires which are formed at the other side of the plurality of semiconductor devices; and
a molding part enclosing the plurality of semiconductor devices and formed to expose upper surface parts of the first mold via and the second mold via.

2. The semiconductor package of claim 1, further comprising:
a substrate formed on upper and lower portions of the first mold via and the second mold via.

3. The semiconductor package of claim 2, further comprising:
an external connection terminal connected between the first mold via and the second mold via and the substrate.

4. A semiconductor package, comprising: a first package including a first semiconductor device formed in a multilayer, a plurality of wires electrically connected to both sides of the first semiconductor device, a first mold via electrically connected to the plurality of wires which are formed at one side of the first semiconductor device, a second mold via electrically connected to the plurality of wires which are formed at the other side of the first semiconductor device, and a first molding part enclosing the first semiconductor device and formed to expose upper surface parts of the first mold via and the second mold via; and
a second package including a second substrate and a second semiconductor device formed under the first package.

5. The semiconductor package of claim 4, further comprising:
a first substrate formed over the first package.

6. The semiconductor package of claim 4, further comprising:
a third package formed between the first package and a first substrate.

7. The semiconductor package of claim 4, further comprising:
a first external connection terminal formed between the first package and the second package.

8. The semiconductor package of claim 4, further comprising:
a second external connection terminal formed between the first package and a first substrate.

9. The semiconductor package of claim 6, further comprising:
a third external connection terminal formed between the third package and the first substrate.

10. The semiconductor package of claim 4, wherein the second package further includes a second molding part.

11. A method of manufacturing a semiconductor package, comprising:
preparing a plurality of lower semiconductor devices arrayed in a line;
forming a plurality of wires electrically connecting adjacent devices among the lower semiconductor devices to each other;
forming a molding part to enclose the lower semiconductor device and the wire;
forming a mold via hole to penetrate through the molding part and the wire;
forming a mold via by performing plating on the mold via hole; and
sawing between adjacent two mold via holes to separate the two mold via holes from each other.

12. The method of claim 11, further comprising:
prior to the preparing of the lower semiconductor device, forming the lower semiconductor device arrayed in a line on a protective film; and
after the forming of the molding part, removing the protective film.

13. The method of claim 11, further comprising:
after the forming of the wire,
forming an adhesive on the lower semiconductor device; and
forming an upper semiconductor device on the adhesive.

14. The method of claim 13, wherein the lower semiconductor device and the upper semiconductor device are the same device.

15. The method of claim 13, wherein the lower semiconductor device and the upper semiconductor device are different devices.

16. The method of claim 11, further comprising:
after the forming of the mold via, forming an external connection terminal over the mold via.

17. The method of claim 11, further comprising:
forming a substrate over or under the mold via.
